(19) United States
(12) Patent Application Publication
(10) Pub. No.: US 2025/0337419 A1
(43) Pub. Date: Oct. 30, 2025

(54) CASCADED DUAL-LOOP PHASE-LOCKED LOOP (PLL) FOR LOWERED PHASE NOISE WITH IMPROVED TUNING RANGE

(71) Applicant: The Hong Kong University of Science and Technology, Hong Kong (CN)

(72) Inventors: Chik Patrick YUE, Hong Kong (CN); Li Wang, Hong Kong (CN)

(21) Appl. No.: 19/188,835

(22) Filed: Apr. 24, 2025

Related U.S. Application Data
(60) Provisional application No. 63/637,898, filed on Apr. 24, 2024.

(51) Int. Cl. H03L 7/093; H03L 7/089; H03L 7/107

(52) U.S. Cl. CPC H03L 7/093; H03L 7/0891; H03L 7/1075

(57) ABSTRACT

A cascaded phase-locked loop (PLL) architecture including voltage-controlled oscillators (VCO) may operate in the mmWave and terahertz range. The architecture may include a low-jitter type-II radio-frequency PLL as a first stage and a wideband high-frequency dual-path PLL as a second stage. By using the radiofrequency output from the first stage as a reference, the second stage attenuates VCO phase noise, resulting in reduced overall jitter. Additionally, the first stage may include an AC-coupled charge pump to ensure robust phase noise performance across a wide VCO control voltage range, and a VCO tuning range design scheme may be provided to achieve a wide tuning range without sacrificing jitter performance.

### CROSS-REFERENCE TO RELATED APPLICATIONS

This application claims priority to U.S. Provisional Patent Application No. 63/637,898, filed on Apr. 24, 2024, which is hereby incorporated by reference in its entirety.

### TECHNICAL FIELD

Embodiments of this application relate to phase-locked loops (PLLs). In particular, embodiments of this application relate to cascaded PLLs operating in the millimeter wave (mmWave) and terahertz (THz) range.

### BACKGROUND

PLLs may be used in a variety of application scenarios. For example, PLLs can be integrated in wireline transceiver integrated circuits (ICs) to provide a clean clock to synchronize high-speed data transmission. In addition, PLLs can also be integrated in millimeter wave transceiver circuits to supply a local oscillator (carrier) signal with very low phase noise. A function of a PLL is to generate an output signal whose frequency is accurately N times the reference frequency which is generated by a crystal oscillator, where N is an integer. A PLL is typically structured in a loop that includes a voltage-controlled oscillator (VCO), a phase detector, and a low-pass filter to assist with frequency locking.

Utilizing PLLs to lock the phase of a signal to a reference signal can reduce phase noise. However, conventional charge pump (CP) designs for PLLs suffer from performance limitations caused by charge sharing and channel length modulation issues. FIG. 1 depicts an example of a conventional CP architecture. As can be seen in FIG. 1, the transconductance (Gm) of the CP is kept relatively small to minimize noise. However, this requires M₁ and M₂ to have increased channel lengths for better matching. As a consequence, the offset current due to charge sharing from the large parasitic capacitance (Cₚₐᵣ) can reach the same level as the biasing current of M₁ and M₂, especially when considering a narrow charging pulse. Additionally, the different on/off transition times of the P and NMOS switches further contribute to offset current issues. These issues result in degraded phase noise due to the deviation of the sampling point in the phase detector from the maximum slope, as well as the injection of additional charging current noise.

Further, conventional voltage-controlled oscillators (VCO) of integrated phase-locked loops (PLLs) operating in the millimeter Wave and terahertz range suffer from phase noise degradation and jitter issues.

### SUMMARY

In an exemplary embodiment, the present application provides a cascaded phase-locked loop (PLL) system. The cascaded PLL system includes: a first stage comprising a type-II loop, wherein the first stage is configured to operate at a first operation frequency; and a second stage comprising a dual-path loop, wherein the second stage is configured to operate at a second operation frequency. A ratio of the second operation frequency to the first operation frequency is an integer greater than 2.

In a further exemplary embodiment, the type-II loop includes a voltage-controlled oscillator (VCO), a phase detector, a charge pump, a second-order loop filter, and a divider.

In a further exemplary embodiment, the dual-path loop includes a proportional path and an integral path.

In a further exemplary embodiment, the proportional path includes a passive loop filter, and wherein the integral path includes a charge pump and a loop filter.

In a further exemplary embodiment, the first stage comprises a first voltage-controlled oscillator (VCO) having a first tuning range; the second stage comprises a second VCO having a second tuning range; and the second tuning range fully encompasses and is wider than the first tuning range.

In a further exemplary embodiment, the first stage comprises an alternating current (AC)-coupled charge pump (ACCP) and a loop filter, wherein the ACCP is configured to isolate an output of the ACCP from the loop filter.

In a further exemplary embodiment, the ACCP comprises: an output; and an AC-coupling capacitor configured to isolate the output from the loop filter.

In a further exemplary embodiment, the ACCP further comprises: a level alignment loop disposed between the AC-coupling capacitor and the loop filter, the level alignment loop comprising a unit-gain amplifier configured to align a direct current (DC) voltage level of the loop filter with a respective plate of the AC-coupling capacitor.

In a further exemplary embodiment, the ACCP further comprises: a dummy charge pump disposed between the output and the AC-coupling capacitor configured to maintain a preset voltage level.

In a further exemplary embodiment, the preset voltage level corresponds to VDD/2.

In a further exemplary embodiment, the first stage comprises a first voltage-controlled oscillator (VCO) having a first tuning range, wherein a quality factor (Q) of an LC tank in the first VCO is optimized with respect to the first tuning range.

In a further exemplary embodiment, the first stage further comprises a frequency-locked loop.

In a further exemplary embodiment, the first stage comprises: a first phase detector configured to receive a reference signal; an alternating current (AC)-coupled charge pump (ACCP) coupled to the phase detector; a first loop filter coupled to the ACCP; a first voltage-controlled oscillator (VCO) coupled to the loop filter; and a first buffer coupled to the first VCO and the first phase detector.

In a further exemplary embodiment, the second stage comprises: a reference buffer coupled to the first VCO; a second phase detector coupled to the reference buffer; a second voltage-controlled oscillator (VCO) coupled to the phase detector via a first path and a second path, wherein the first path comprises a passive loop filter and the second path comprises a charge pump and a loop filter; a second buffer coupled to the second VCO and to the second phase detector.

In yet another exemplary embodiment, the present invention provides an alternating current (AC)-coupled charge pump (ACCP). The ACCP includes: an output; an AC-coupling capacitor configured to isolate the output from a loop filter; and a level alignment loop disposed between the AC-coupling capacitor and the loop filter, the level alignment loop comprising a unit-gain amplifier configured to align a direct current (DC) voltage level of the loop filter with a respective plate of the AC-coupling capacitor.

In a further exemplary embodiment, the ACCP further includes: a dummy charge pump disposed between the output and the AC-coupling capacitor configured to maintain a preset voltage level.

In a further exemplary embodiment, the preset voltage level corresponds to VDD/2.

In yet another exemplary embodiment, the present invention provides an alternating current (AC)-coupled charge pump (ACCP). The ACCP includes: an output; an AC-coupling capacitor configured to isolate the output from a loop filter; and a dummy charge pump disposed between the output and the AC-coupling capacitor configured to maintain a preset voltage level.

In a further exemplary embodiment, the ACCP further includes: a level alignment loop disposed between the AC-coupling capacitor and the loop filter, the level alignment loop comprising a unit-gain amplifier configured to align a direct current (DC) voltage level of the loop filter with a respective plate of the AC-coupling capacitor.

In a further exemplary embodiment, the preset voltage level corresponds to VDD/2.

### BRIEF DESCRIPTION OF DRAWINGS

FIG. 1 depicts an example of a conventional charge pump (CP) architecture;

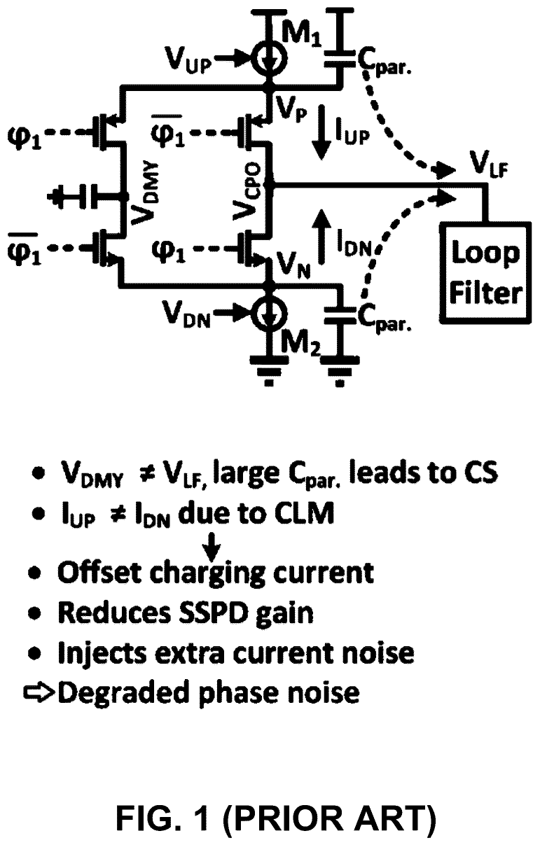

FIG. 2A depicts an example of an overall structure of a cascaded PLL according to an exemplary embodiment of the present application;

FIG. 2B depicts an example of a detailed architecture of a cascaded PLL according to an exemplary embodiment of the present application;

FIG. 3 depicts an example of an AC-coupled charge pump (ACCP) according to an exemplary embodiment of the present application;

FIG. 4 depicts example simulations of CP output node voltage and charging current waveforms of an ACCP according to an exemplary embodiment of the present application and of a conventional CP;

FIG. 5 depicts an example of a tuning range design scheme for two VCOs according to an exemplary embodiment of the present application;

FIG. 6 depicts exemplary implementations of a Class-C VCO (part (a)), a VCO inductor (part (b)), and a VCO buffer (part (c)) for an exemplary embodiment of the present application;

FIG. 7 depicts an example of measured phase noise and integrated jitter of a cascaded PLL which includes a first-stage 7-GHz PLL and a second-stage 28-GHz quadrature PLL (QPLL) in accordance with an exemplary implementation of the present application; and

FIG. 8 depicts an example comparison of measured phase noises for an ACCP and a conventional CP.

### DETAILED DESCRIPTION

Exemplary embodiments of the present application provide a cascaded PLL architecture which includes an AC-coupled charge pump (ACCP) so as to achieve reduced phase noise. Phase noise reduction is advantageous, for example, for providing precise timing and signal stability in high-speed communication systems, as well as for enhancing signal quality, especially for high-frequency wireless and radar systems, where a clean and stable signal is required without unwanted phase fluctuations.

In an exemplary embodiment, a cascaded integrated phase-locked loop (PLL) architecture is provided to address the phase noise degradation in the voltage-controlled oscillator (VCO) of integrated phase-locked loops (PLLs) operating in the millimeter-wave (mmWave) and terahertz range. The PLL architecture includes a first stage—a low-jitter type-II radiofrequency PLL—and a second stage—a wideband high-frequency dual-path PLL. A type-II PLL is characterized by a loop structure that includes a voltage-controlled oscillator (VCO), a phase detector, a charge pump, a second-order loop filter, and a divider. The transfer function of a type-II PLL contains two poles at the origin, which are contributed by the VCO and the integration capacitor in the second-order loop filter. By using the radiofrequency output from the first stage as the reference, the second stage attenuates the VCO phase noise, resulting in reduced overall jitter. The ACCP ensures robust phase noise performance across a wide VCO control voltage range. Additionally, a VCO tuning range design scheme is provided to achieve a wide tuning range without sacrificing jitter performance. According to the provided PLL architecture, improvements in jitter performance and the frequency tuning range in mm Wave and terahertz PLLs can be achieved.

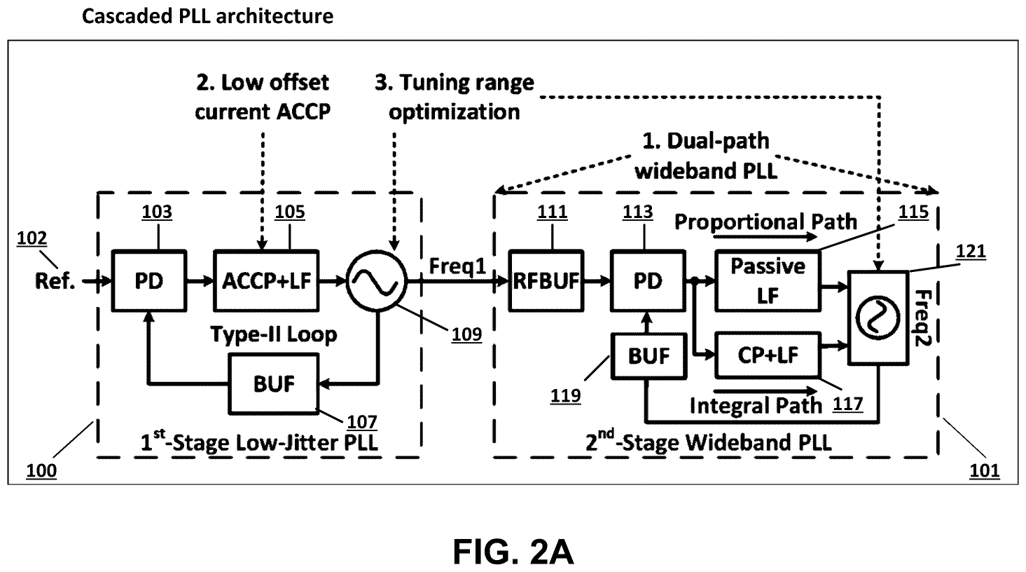

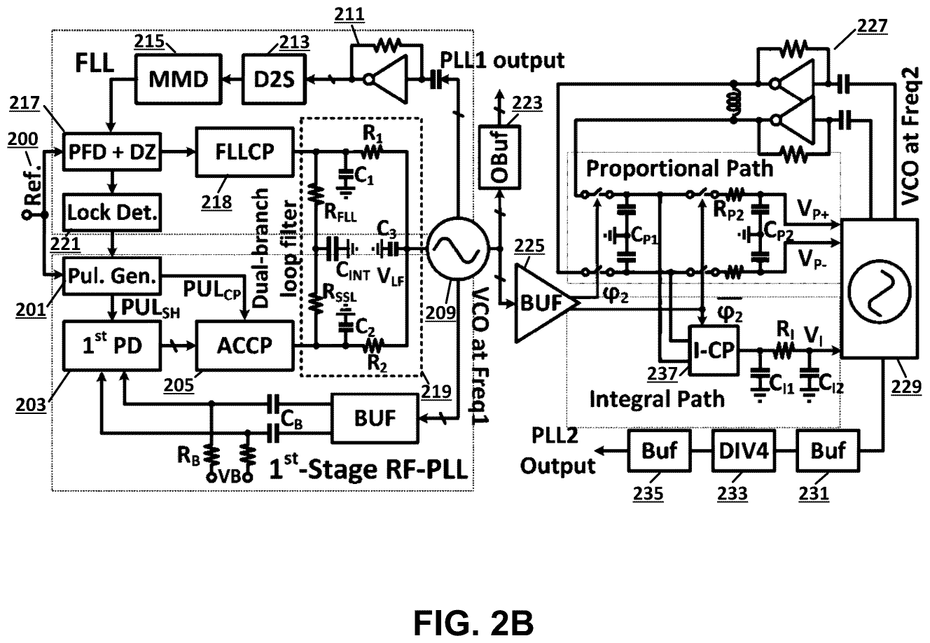

FIG. 2A depicts an example of an overall structure of a cascaded PLL according to an exemplary embodiment of the present application. In a first stage 100, a radiofrequency (RF) type-II phase-locked loop (PLL) is employed to generate an output with low jitter and low spur at Freq1. In the first stage “low-jitter PLL” 100, reference signal (“Ref.”) 102 is input to phase detector (PD) 103 for phase detection. The output of PD 103 is provided to an ACCP and loop filter (LF) (“ACCP+LF”) 105. The ACCP addresses the offset current issue and reduces the phase noise contribution. The frequency of the first VCO 109 is controlled by the output of ACCP+LF 105, and the first VCO 109 outputs the result to buffer 107, which further feeds the signal back to the PD 103. VCO 109 also outputs a signal (having jitter lower than 60 fs and spur lower than −70 dBc) at a first frequency (“Freq1”) to second stage 101. The frequency tuning range of the first VCO 109 is optimized so that the VCO can provide the optimal phase noise performance, for example, reaching a phase noise-power figure-of-merit of better than −190 dB.

The 1st-stage PLL 100 is able to achieve low-jitter through two factors. First, VCO 109 in the 1st-stage PLL operates at a low frequency range (e.g., below 10 GHz), which is much lower compared to second-stage millimeter-wave (mmWave) or terahertz VCOs. As a result, an inductor-capacitor tank (LC tank) in the first VCO 109 exhibits a significantly improved quality factor, primarily due to enhancements in the switchable capacitor bank. Second, as mentioned above, the ACCP addresses the offset current issues and thus reduces the phase noise contribution from the offset current. The overall loop maintains a robust bandwidth over a wide range of VCO control voltage variations.

The 1^{st}-stage PLL 100 is also able to achieve low spur performance, mainly due to being a type-II architecture, where a large integration capacitor together with a following low-pass filter in ACCP+LF 105 helps reduce the VCO control voltage variation due to the charge pump.

The second stage PLL 101 operates at a second frequency (“Freq2”) higher than the first frequency Freq1. The second frequency Freq2 may be N times the frequency of the first stage, where N is any integer greater than 2. The signal output by the 1^{st}-stage PLL 100 (which is at Freq1) is input to the 2^{nd}-stage PLL 101 at reference buffer (RFBUF) 111. RFBUF 111 isolates the coupling between the VCO and the PD, which enhances driving capability. The output of RFBUF 111 is provided to PD 113 for phase detection. The output of PD 113 is provided to passive loop filter (LF) 115 and charge pump (CP)+LF 117. The passive LF 115 is configured to filter the PD output and generate a stable voltage signal for controlling a VCO, and the CP+LF 117 is configured to enhance the gain of the integral path (the CP converts the voltage signal from the PD to a charging and discharging current signal, and the LF then converts the charging and discharging current back to the voltage domain). Both signals output from passive LF 115 and CP+LF 117 are provided to a second VCO 121 for frequency tuning to obtain an output signal at Freq2. The output signal of the VCO 121 at Freq 2 is provided to buffer (BUF) 119, which isolates the coupling between the VCO and PD for enhancing driving capability, and the output of BUF 119 is fed back to PD 113 to form a closed loop to achieve phase locking.

The second-stage PLL 101 utilizes a dual-path architecture that includes a passive proportional path and an integral path. This implementation offers two advantages. First, the in-band phase noise of the passive proportional path is lower compared to active implementations. Second, the integral path is responsible solely for capturing the frequency error. Consequently, a small charge pump gain is sufficient for this function, enabling the use of small and area-efficient integration capacitors for loop filters in passive LF 115 and CP+LF 117. Since the frequency error is entirely captured by the integral path, the phase detector (PD) gain can be significantly increased, contributing for a large PLL loop bandwidth that effectively attenuates the phase noise contribution from the second stage VCO 121. Consequently, although the second stage VCO 121 operates at a high frequency and exhibits significant larger phase noise compared to the first stage VCO 109, the overall PLL jitter performance remains unaffected due to the wide bandwidth of the second stage PLL 101.

FIG. 2B depicts an example of a detailed architecture of a cascaded PLL according to an exemplary embodiment of the present application. The 1st-stage PLL includes a phase-locked loop (PLL) and an additional frequency-locked loop (FLL) that aids in the initial frequency lock-in process. In the phase-locked loop (PLL), pulse generator (“Pul. Gen.”) 201 generates a sampling pulse and a charge pump pulse derived from a reference signal (“Ref.”) 200, which are used to control a first phase detector (“PD”) 203 and AC-coupled charge pump (ACCP) 205, respectively. In the frequency-locked loop (FLL), the output from the Voltage-Controlled Oscillator (VCO) 209 is AC-coupled into a resistive-feedback amplifier 211. The output of the AC-coupled amplifier is converted into a single-ended signal using a differential-to-single-ended converter (D2S) 213 to feed into the subsequent multi-modulus divider (MMD). The MMD 215 operates digitally and uses a single-ended input. It is used to adjust the multiplication ratio between the VCO frequency and the reference frequency. A phase and frequency detector (PFD) with a dead zone (DZ), denoted as “PFD+DZ” 217, is utilized to facilitate wide-range frequency error detection between the reference signal (Ref.) and the output of the MMD 215.

The output from the PFD+DZ 217 in the FLL is fed to an FLLCP (FLL charge pump) 218 to charge the loop filter. The PLL and the FLL interact with each other through a dual-branch loop filter 219. This dual-branch loop filter 219 enables separate optimization of the stabilization resistors for the PLL and FLL, respectively. Since the phase detector of the FLL's PFD (part of PFD+DZ 217) is significantly smaller than that of the PLL's phase detector 203, employing a larger stabilization resistor for the FLL and a smaller stabilization resistor for the PLL can enhance the phase margin and phase noise performance of both loops.

The output of the first stage is amplified by buffer 225 and serves as the reference signal for the second stage PLL (“PLL2”). The center frequency of the second stage PLL is N times that of the first stage PLL, where N is an integer typically ranging from 2 to 10. For example, if the frequency of the first stage PLL is configured as 7 GHZ, the frequency of the second stage PLL can be designed to be 14 GHz, 21 GHz, 28 GHz, or even higher, depending on the specific requirements and system constraints.

Despite the first-stage output frequency falling within a few GHz, the second stage is designed to support a wide bandwidth, reaching tens of MHz or even exceeding 100 MHZ, even when using a passive proportional path. To address frequency errors between the reference signal and the VCO, an integral path is incorporated. This integral path includes an integral charge pump (I-CP) 237, which charges and discharges a C-R-C loop filter composed of C_{I1}, C_{I2}, and R_{I}. The I-CP 237 and C-R-C combination provides high open-loop gain at low frequencies, enabling the capture of frequency errors. By tracking these frequency errors through the integral path, the gain of the proportional path can be maximized, allowing for a wide loop bandwidth. This configuration ensures that the second stage maintains a robust and wide loop bandwidth, even in the presence of significant initial frequency errors. In the feedback path, an inverter-based buffer with a peaking inductor is employed to generate a sufficiently large swing in the feedback signal. This large swing enhances the loop bandwidth, contributing to improved overall performance.

For measurement purposes, the phase noise of the first-stage PLL and second-stage PLL are characterized individually. In the first stage, an output buffer (OBUF) 223 is used to enhance the signal strength at the VCO output and route it off-chip for measurement. In the second stage, which serves as the overall output of the cascaded PLL, the signal from the VCO 229 of the second stage is first buffered using buffer (Buf) 231, then divided by 4 using the divide-by-4 module (“DIV4”) 233, and finally routed through another output buffer (Buf) 235 to the off-chip measurement interface. The divide-by-4 module DIV4 233 reduces the output frequency, simplifying signal distribution to the output and mitigating signal loss during the distribution process. The output of VCO 229 is also provided to a VCO buffer 227 and fed back to the two paths. The VCO buffer 227 is designed with a resistive-feedback topology and incorporates a shunt inductor to enhance its operating bandwidth. This buffer isolates the proportional and integral paths from the VCO, safeguarding the phase noise and spur performance of the VCO.

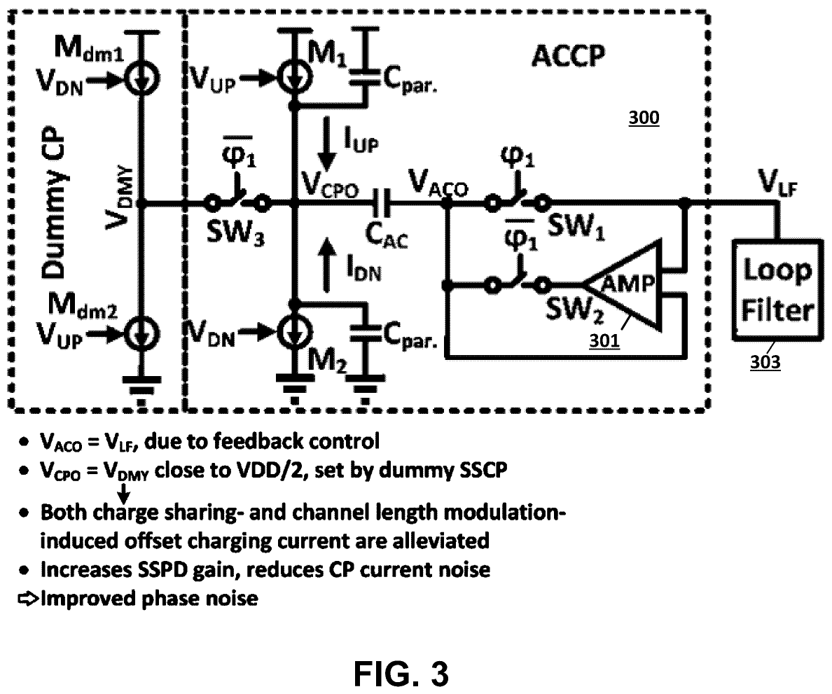

FIG. 3 depicts an example of an ACCP according to an exemplary embodiment of the present application. The drain nodes of M₁ and M₂ are directly connected without the use of separate P and NMOS switches. Instead, switches SW₁ to SW₃ are implemented using transmission gates to eliminate the transition time differences. The ACCP incorporates a coupling capacitor (C_{AC}) to isolate V_{CPO} (output voltage of the VCO) from V_{LF} (loop filter voltage). φ₁ and φ̅₁̅ refer to the positive and opposite phases of the charging pulse (PUL_{CP}) shown in FIG. 2B. When the charging pulse PUL_{CP} is turned off, a rail-to-rail amplifier (RRAMP) 301 in a unit-gain feedback configuration aligns V_{ACO} (VCO output voltage) with VLF, while a dummy charge pump (CP) keeps V_{CPO} close to VDD/2. When PUL_{CP} is turned on, capacitor C_{AC} and loop filter 303 form a much lower impedance path compared to the drain nodes of M₁ and M₂, allowing the charging current to flow into the loop filter without disturbing V_{CPO}. By aligning the voltage across SW₁ to be equal and keeping V_{CPO} close to VDD/2, the issues of charge sharing and channel length modulation can be mitigated effectively.

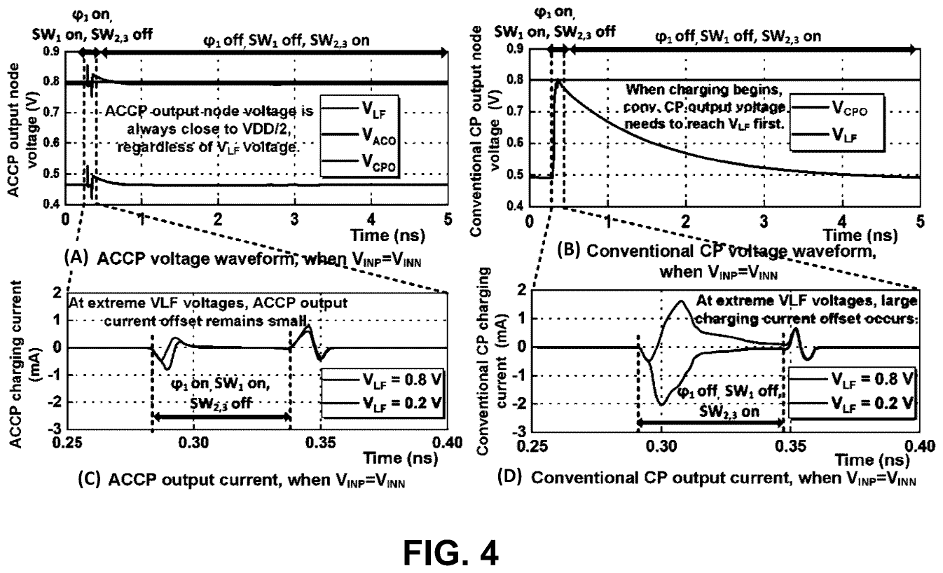

FIG. 4 shows example simulations of CP output node voltage and charging current waveforms of an ACCP and a conventional CP. This post-layout simulation was performed to verify the performance of an ACCP according to an exemplary implementation. In the simulation setup, the differential input to both ACCP and conventional CP are set to be the same. Therefore, ideally the CP should not produce any output charging current. By sweeping across differential output loop filter voltage, the simulated waveforms in FIG. 4 demonstrate that V_{CPO} remains constantly at 0.47 V while V_{ACO} is accurately aligned to V_{LF} at 0.8 V. In contrast, conventional source-switched charge pump (SSCP) output V_{CPO} is pulled to V_{LF} instantly when SW₁ is turned on. The simulated output current in parts (C) and (D) show that the AC-SSCP effectively suppress the offset current compared to a conventional SSCP when V_{LF} is set to 0.2 and 0.8 V.

When cascading two loops, tuning range misalignment may occur between the first and second stage PLLs, which may result in a reduced overall tuning range. To address this issue, exemplary embodiments of the present application further provides a tuning range design scheme for the first and second VCOs for ensuring sufficient tuning range without degrading the overall phase noise performance.

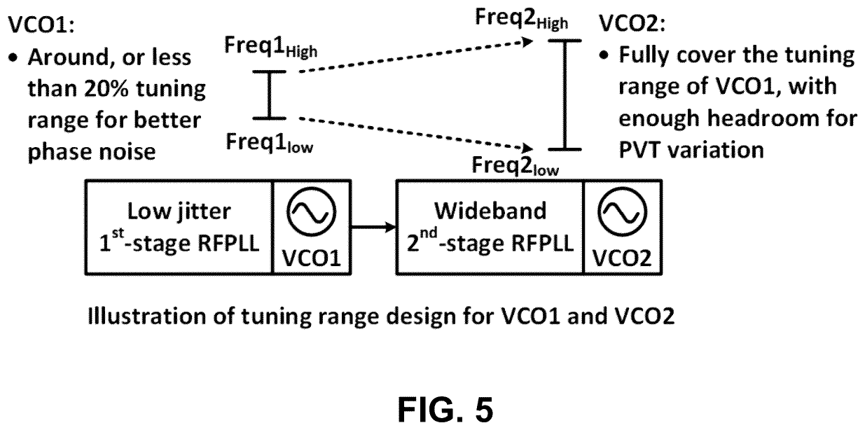

FIG. 5 depicts an example of a tuning range design scheme for two VCOs (VCO1 and VCO2) according to an exemplary embodiment of the present application. Although increasing the tuning range of both VCO1 and VCO2 can enhance the overall tuning range, such an approach would reduce the quality factor of the switchable capacitor bank and lead to higher jitter. Since the wideband of the second-stage PLL can sufficiently attenuate the phase noise of VCO2, the tuning range optimization can be performed as described below.

Initially, the frequency tuning range of the first-stage VCO is established to meet the targeted application requirements. This is accomplished through the appropriate implementation of the inductor-capacitor tank. The inductor value is selected based on a trade-off between power consumption and phase noise: a smaller inductor value improves phase noise but increases overall power consumption. Following the selection of the inductor, the capacitor bank tuning range is determined to support the expected frequency tuning range, with additional headroom to accommodate PVT variations. Subsequently, the tuning range of the second-stage VCO is determined. This tuning range should be sufficiently wide to fully cover the tuning range of the first stage, ensuring that the first-stage VCO's tuning range is not wasted. Although a wide tuning range can degrade phase noise, the cascaded architecture allows the second-stage PLL's wide bandwidth to regulate the degraded phase noise of the VCO. This design ensures a wide overall PLL tuning range and low overall phase noise, which is primarily determined by the first-stage PLL.

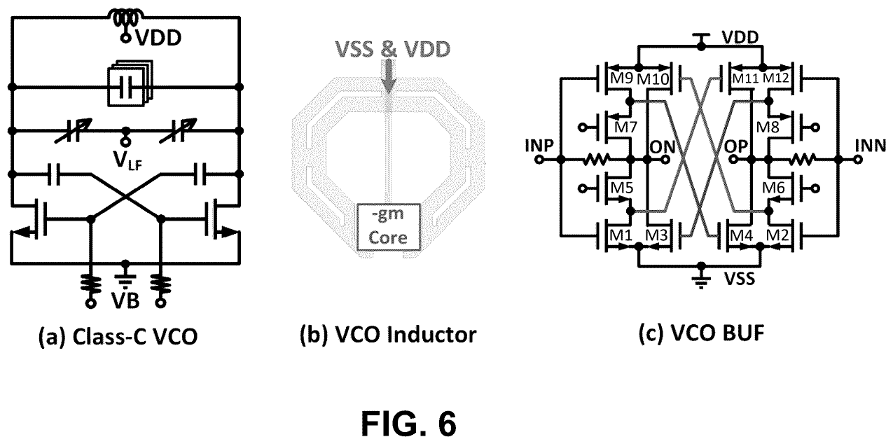

FIG. 6 depicts exemplary implementations of a Class-C VCO (part (a)), a VCO inductor (part (b)), and a VCO buffer (part (c)) for an exemplary embodiment of the present application. As shown in part (a) of FIG. 6, to achieve better phase noise, class-C topology is adopted for the first-stage PLL, in which the noise injection window of the active MOSFETS device in each cycle is narrower than class-B VCO. The bias level can be optimized to achieve a better phase noise. As the first stage VCO is operating at GHz level, the inductor quality factor is important to support a good phase noise.

The inductor for the VCO depicted in part (b) of FIG. 6 is designed with a compact area and a short signal return path. The active devices (-gm core), typically placed outside the inductor, are integrated within the inductor region. This integration helps to minimize the parasitic resistance associated with the interconnection metal and reduces the overall VCO chip area. Additionally, the power routing, depicted as the vertical gray line starting from VSS and VDD to the active devices (-gm core), is routed directly underneath the inductor at the center. This routing approach achieves a symmetric and straightforward power distribution. The power routing provides an explicit return path for the oscillation signal back to VDD and VSS, ensuring the shortest possible return path. Furthermore, since the power routing is positioned at the AC ground of the inductor, it has negligible impact on the inductor's quality factor.

The VCO buffer is depicted in part (c) of FIG. 6. The VCO differential output is fed into INP and INN, driving the input transistors M1, M2, M9, and M12. After being amplified by the buffer, the signal is output from ON and OP and proceeds to the next stage. The VCO buffer is designed to achieve high output swing and wide bandwidth through three key techniques. First, cascaded P/NMOS transistors (M5-M8) isolate the buffer's input and output nodes, effectively decoupling the VCO from the phase detector and minimizing spurious signals caused by feedback. Second, two pairs of -gm transistors (M3-M4 and M10-M11) are incorporated to enhance bandwidth, enabling the buffer to handle high-frequency signals efficiently. Finally, the gate nodes of the P/NMOS -gm pairs are connected to the low-resistance source nodes of the cascaded devices on the opposite side of the differential topology, allowing the buffer to accommodate significant parasitic capacitance without degrading bandwidth performance.

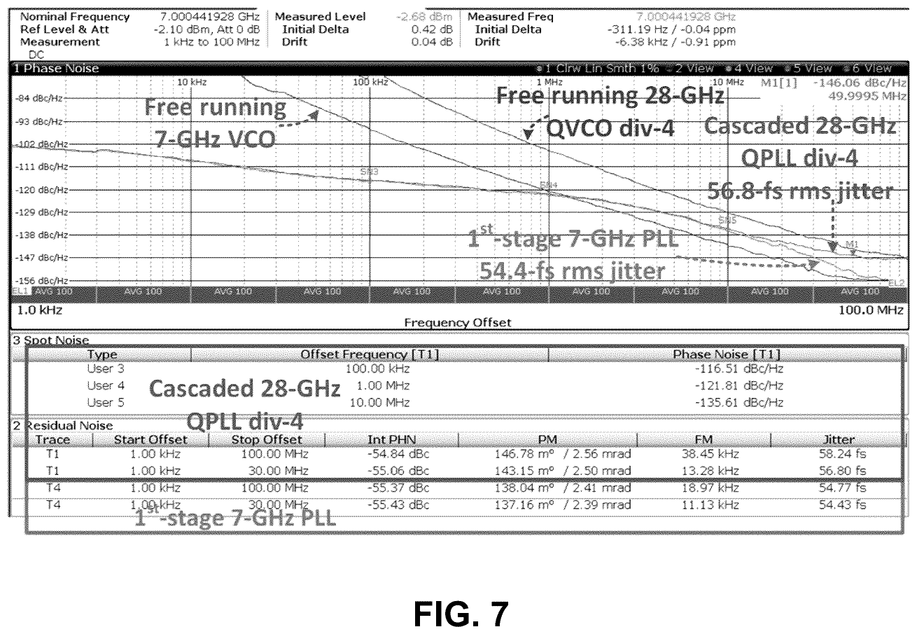

FIG. 7 depicts an example of measured phase noise and integrated jitter of a cascaded PLL which includes a first-stage 7-GHz PLL and a second-stage 28-GHz quadrature PLL (QPLL) in accordance with an exemplary implementation of the present application. The cascaded PLL includes a 7-GHz first-stage PLL, cascaded with a second-stage 28-GHz QPLL. With a 250-MHz reference, the measured phase noises of free running (FR) 7-GHz VCO, 28-GHz VCO div-4, 7-GHz PLL and 28-GHz PLL div-4 output are shown in FIG. 7. Integrated from 1 kHz to 30 MHz, the 7-GHz and 28-GHz PLL achieves an integrated rms jitter of 54.43 and 56.8 fs, respectively. The 1st stage PLL phase noise (PN) curve is smooth and without PN peaking, demonstrating sufficient loop bandwidth. The 28-GHz PLL PN curve converges with 28-GHz FR VCO only when the offset frequency reaches 100 MHz, validating the wide loop bandwidth provided by the 2nd stage dual path (DP)-PLL.

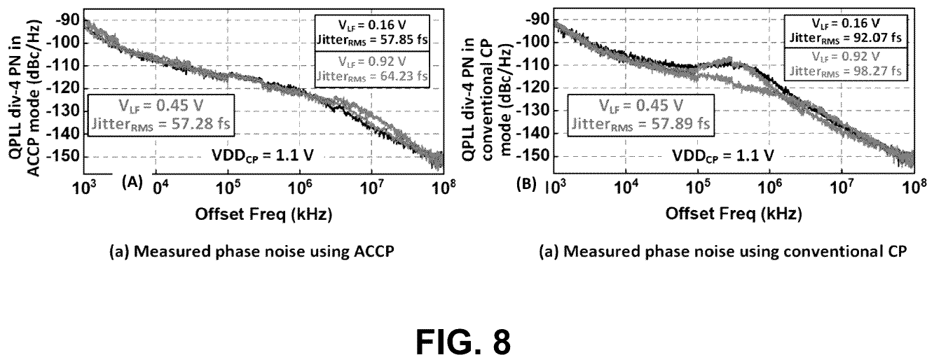

FIG. 8 depicts an example comparison of measured phase noises for an ACCP and a conventional CP. To verify the ACCP performance under different V_{LF} levels, the 7-GHz VCO capbank control code is adjusted until V_{LF} reaches 0.45 V, 0.16 V and 0.92 V when VDD_{CP} is equal to 1.1 V. A on-chip switch can be switched on to enable the ACCP, or switched off to short the AC coupling capacitor, and open the connection between main SSCP and dummy SSCP, which becomes a conventional SSCP topology. As shown in FIG. 8, the ACCP and conventional CP show almost the same performance when V_{LF} is equal to 0.45 V. However, the conventional CP significantly narrows down the loop bandwidth due to reduced phase-detection (PD) gain, and degrades the PN when V_{LF} is equal to 0.16 and 0.92 V. For ACCP, the PN profile and jitter only shows a variation of 6.95 fs from 57.28 to 64.23 femtoseconds (fs).

It will be appreciated that the execution of the various machine-implemented processes and steps described herein may occur via the execution, by one or more respective processors, of processor-executable instructions stored on one or more tangible, non-transitory computer-readable mediums (such as random access memory (RAM), read-only memory (ROM), programmable read-only memory (PROM), and/or another electronic memory mechanism). Thus, for example, operations performed by various components as discussed herein may be carried out according to instructions stored on and/or applications installed on one or more respective computing devices.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A cascaded phase-locked loop (PLL) system, comprising:
a first stage comprising a type-II loop, wherein the first stage is configured to operate at a first operation frequency; and
a second stage comprising a dual-path loop, wherein the second stage is configured to operate at a second operation frequency;
wherein a ratio of the second operation frequency to the first operation frequency is an integer greater than 2.

2. The cascaded PLL system according to claim 1, wherein the type-II loop includes a voltage-controlled oscillator (VCO), a phase detector, a charge pump, a second-order loop filter, and a divider.

3. The cascaded PLL system according to claim 1, wherein the dual-path loop includes a proportional path and an integral path.

4. The cascaded PLL system according to claim 3, wherein the proportional path includes a passive loop filter, and wherein the integral path includes a charge pump and a loop filter.

5. The cascaded PLL system according to claim 1, wherein the first stage comprises a first voltage-controlled oscillator (VCO) having a first tuning range;
wherein the second stage comprises a second VCO having a second tuning range; and
wherein the second tuning range fully encompasses and is wider than the first tuning range.

6. The cascaded PLL system according to claim 1, wherein the first stage comprises an alternating current (AC)-coupled charge pump (ACCP) and a loop filter, wherein the ACCP is configured to isolate an output of the ACCP from the loop filter.

7. The cascaded PLL system according to claim 6, wherein the ACCP comprises:
an output; and
an AC-coupling capacitor configured to isolate the output from the loop filter.

8. The cascaded PLL system according to claim 7, wherein the ACCP further comprises:
a level alignment loop disposed between the AC-coupling capacitor and the loop filter, the level alignment loop comprising a unit-gain amplifier configured to align a direct current (DC) voltage level of the loop filter with a respective plate of the AC-coupling capacitor.

9. The cascaded PLL system according to claim 7, wherein the ACCP further comprises:
a dummy charge pump disposed between the output and the AC-coupling capacitor configured to maintain a preset voltage level.

10. The cascaded PLL system according to claim 9, wherein the preset voltage level corresponds to VDD/2.

11. The cascaded PLL system according to claim 1, wherein the first stage comprises a first voltage-controlled oscillator (VCO) having a first tuning range, wherein a quality factor (Q) of an LC tank in the first VCO is optimized with respect to the first tuning range.

12. The cascaded PLL system according to claim 1, wherein the first stage further comprises a frequency-locked loop.

13. The cascaded PLL system according to claim 1, wherein the first stage comprises:
a first phase detector configured to receive a reference signal;
an alternating current (AC)-coupled charge pump (ACCP) coupled to the phase detector;
a first loop filter coupled to the ACCP;
a first voltage-controlled oscillator (VCO) coupled to the loop filter; and
a first buffer coupled to the first VCO and the first phase detector.

14. The cascaded PLL system according to claim 13, wherein the second stage comprises:
a reference buffer coupled to the first VCO;
a second phase detector coupled to the reference buffer;
a second voltage-controlled oscillator (VCO) coupled to the phase detector via a first path and a second path, wherein the first path comprises a passive loop filter and the second path comprises a charge pump and a loop filter;
a second buffer coupled to the second VCO and to the second phase detector.

15. An alternating current (AC)-coupled charge pump (ACCP), comprising:
an output;
an AC-coupling capacitor configured to isolate the output from a loop filter; and
a level alignment loop disposed between the AC-coupling capacitor and the loop filter, the level alignment loop comprising a unit-gain amplifier configured to align a direct current (DC) voltage level of the loop filter with a respective plate of the AC-coupling capacitor.

16. The ACCP according to claim 15, further comprising:
a dummy charge pump disposed between the output and the AC-coupling capacitor configured to maintain a preset voltage level.

17. The ACCP according to claim 16, wherein the preset voltage level corresponds to VDD/2.

18. An alternating current (AC)-coupled charge pump (ACCP), comprising:
an output;
an AC-coupling capacitor configured to isolate the output from a loop filter; and
a dummy charge pump disposed between the output and the AC-coupling capacitor configured to maintain a preset voltage level.

19. The ACCP according to claim 18, further comprising:
a level alignment loop disposed between the AC-coupling capacitor and the loop filter, the level alignment loop comprising a unit-gain amplifier configured to align a direct current (DC) voltage level of the loop filter with a respective plate of the AC-coupling capacitor.

20. The ACCP according to claim 18, wherein the preset voltage level corresponds to VDD/2.
